(19) United States
(12) Patent Application Publication
(10) Pub. No.: US 2006/0057853 A1
(43) Pub. Date: Mar. 16, 2006

(54) Thermal oxidation for improved silicide formation

(76) Inventors: Manoj Mehrotra, Plano, TX (US); Freidoon Mehrad, Plano, TX (US); F. Scott Johnson, Richardson, TX (US)

Correspondence Address: TEXAS INSTRUMENTS INCORPORATED, P O BOX 655474, M/S 3999, DALLAS, TX, 75265, US

(21) Appl. No.: 10/943,086

(22) Filed: Sep. 15, 2004

(51) Int. Cl. H01L 21/461; B08B 6/00; H01L 21/302

(52) U.S. Cl. 438/706; 438/710; 216/67; 438/745; 134/1.2

(57) ABSTRACT

An embodiment of the invention is a method for improving the uniformity of silicide 190 in semiconductor wafers 10. The method may include etching source/drain sidewall spacers 150, performing an oxidation of semiconductor wafer 10, and then performing a wet clean of semiconductor wafer 10.

### BACKGROUND OF THE INVENTION

This invention relates to the improvement of silicide uniformity over active silicon areas of semiconductor wafers.

### BRIEF DESCRIPTION OF THE DRAWINGS

FIG. 1 is a cross-sectional view of a partially fabricated semiconductor wafer in accordance with the present invention.

FIGS. 2A-2N are cross-sectional diagrams of a process for forming a silicide in accordance with the present invention.

### DETAILED DESCRIPTION OF THE INVENTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

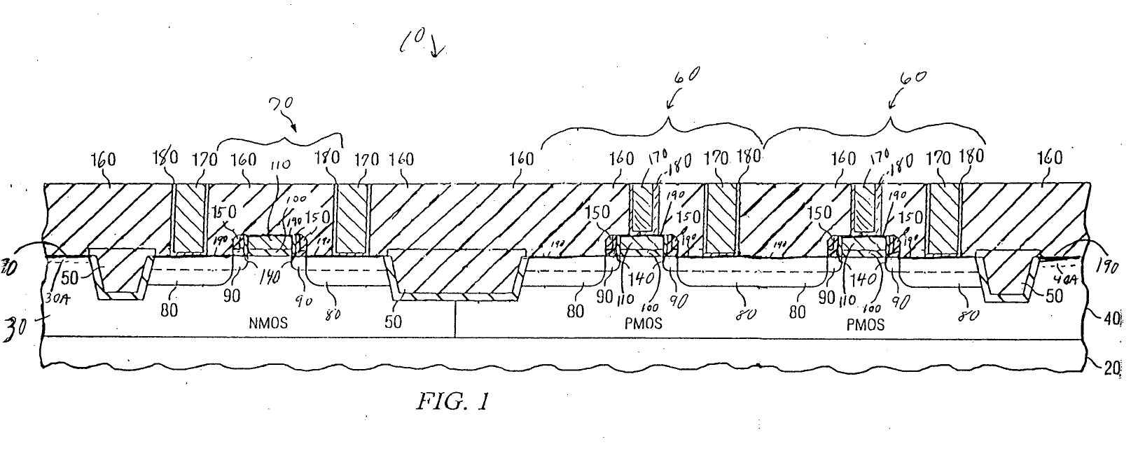

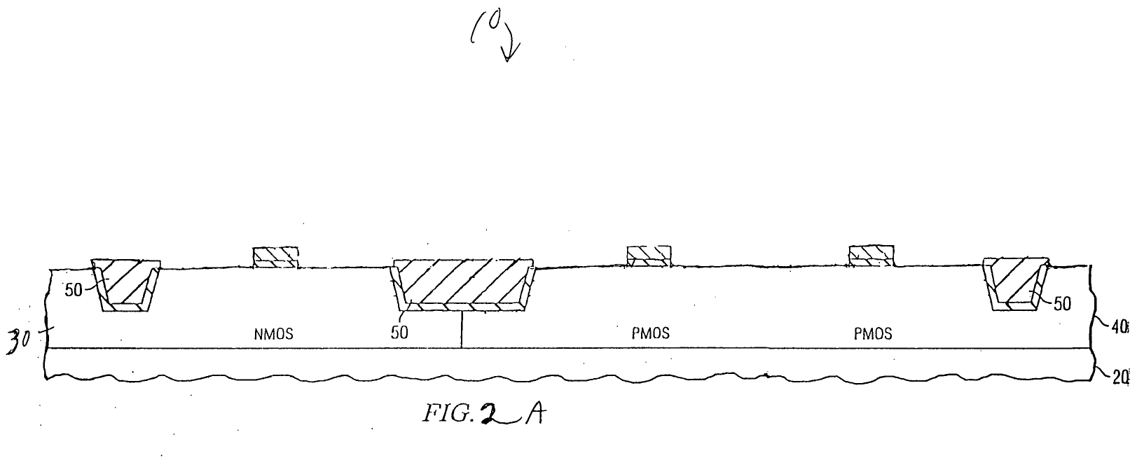

Referring to the drawings, FIG. 1 is a cross-sectional view of a partially fabricated semiconductor wafer 10 in accordance with the present invention. In the example application, CMOS transistors 60, 70 are formed within a semiconductor substrate 20 having an NMOS region 30 and a PMOS region 40. However, it is within the scope of the invention to use a semiconductor wafer 10 that contains any one of a variety of semiconductor devices, such as bipolar junction transistors, capacitors, or diodes.

The CMOS transistors 60, 70 are electrically insulated from other active devices (not shown) by shallow trench isolation structures 50 formed within the NMOS and PMOS regions 30, 40; however, any conventional isolation structure may be used such as field oxide regions (also known as “LOCOS” regions) or implanted isolation regions. The semiconductor substrate 20 is a single-crystalline substrate that is doped to be n-type and p-type; however, it may be formed by fabricating an epitaxial silicon layer on a single-crystal substrate.

Transistors, such as CMOS transistors 60, 70, are generally comprised of a gate, source, and drain. More specifically, as shown in FIG. 1, the active portion of the transistors are comprised of source and drain regions 80, source and drain extension regions 90, and a gate that is comprised of a gate oxide 100 and a gate polysilicon electrode 110.

The example PMOS transistor 60 is a p-channel MOS transistor. Therefore it is formed within a n-well region 40 of the semiconductor substrate 20. In addition, the source and drain regions 80 (as well as the source and drain extension regions 90, which may be lightly doped (“LDD”), medium doped (“MDD”), or highly doped (“HDD”)) have p-type dopants. The PMOS transistor gate is created from p-type doped polysilicon 110 and a gate oxide dielectric 100.

Similarly, the example NMOS transistor 70 is an n-channel MOS transistor. Therefore it is formed within a p-well region 30 of the semiconductor substrate 20. In addition, the source and drain regions 80 (as well as the LDD, MDD, or HDD source and drain extension regions 90) have n-type dopants. The NMOS transistor gate is created from n-type doped polysilicon 110 and a gate oxide dielectric 100.

A sidewall spacer structure comprising offset layers 140, 150 are used during fabrication to enable the proper placement of the source/drain regions 80 and the source/drain extension regions 90 (described more fully below). The source/drain extension regions 90 are formed using the gate stack 100, 110 and the extension sidewall spacers 140 as a mask. Similarly, the source/drain regions 80 are formed using the gate stack 100, 110 and the source/drain sidewall spacers 150 as a mask.

Immediately above and surrounding the transistors is a layer of dielectric insulation 160. The composition of dielectric insulation 160 may be any suitable material such as SiO₂ or organosilicate glass (“OSG”). The dielectric material 160 electrically insulates the metal contacts 170 that electrically connect the CMOS transistors 60, 70 shown in FIG. 1 to other active or passive devices (not shown) located throughout the semiconductor wafer 10. An optional dielectric liner (not shown) may be formed before the placement of the dielectric insulation layer 160. If used, the dielectric liner may be any suitable material such as silicon nitride.

In the example application, the contacts 170 are comprised of W; however, any suitable material (such as Cu, Ti, or Al) may be used. In addition, an optional liner material 180 such as Ti, TiN, or Ta (or any combination or layer stack thereof) may be used to reduce the contact resistance at the interface between the liner 180 and the silicided regions 190 of the gate electrode 110 and the sources and drains 80.

Subsequent fabrication will create the “back-end” portion (not shown) of the semiconductor wafer 10. The back-end generally contains one or more interconnect layers (and possibly via layers) that properly route electrical signals and power though out the completed integrated circuit.

The fabrication process (described below) will create a layer of silicide 190 over all active silicon areas (as well as over the gate polysilicon 110). As shown in FIG. 1, silicide 190A will also form over active silicon areas 30A, 40A that are not a component of any active device.

One of the main purposes of the silicide layer 190, which is formed over the active silicon areas of the sources and drains 80, is the reduction of the contact resistance between the transistor and the electrical contacts 170. In this example application of the invention, the silicide 190 is CoSi₂. However, it is within the scope of the invention to use a different silicide, such as NiSi.

The silicide 190 formed in accordance with the invention is a complete formation of silicide having a better silicide thickness uniformity due to the cleaner silicon surface prior to the silicidation, which is achieved by the thermal oxidation and wet clean process described below. In addition, this thermal oxidation and wet clean process will reduce the contamination of the source and drain regions 80 that is caused by the plasma etch of the source/drain sidewall spacers 150.

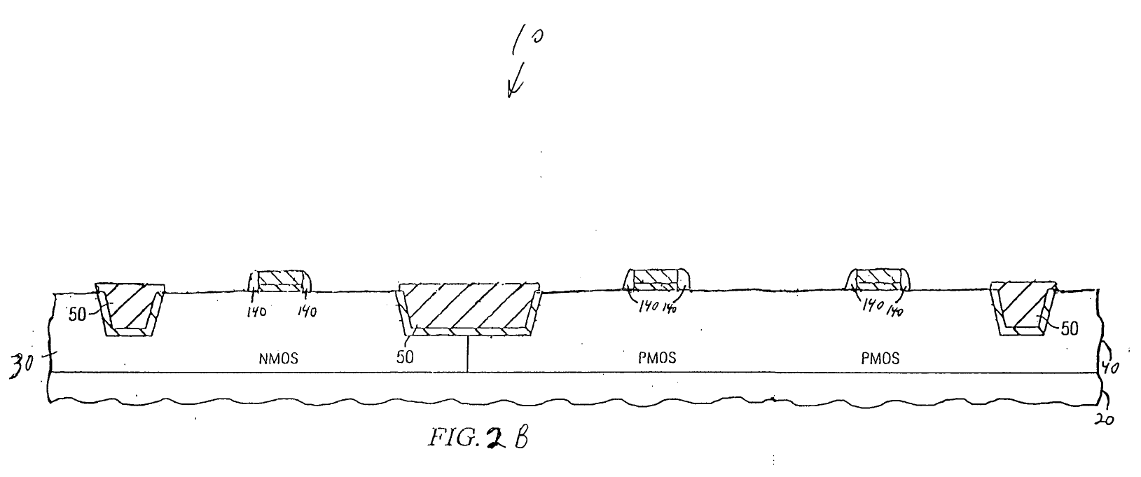

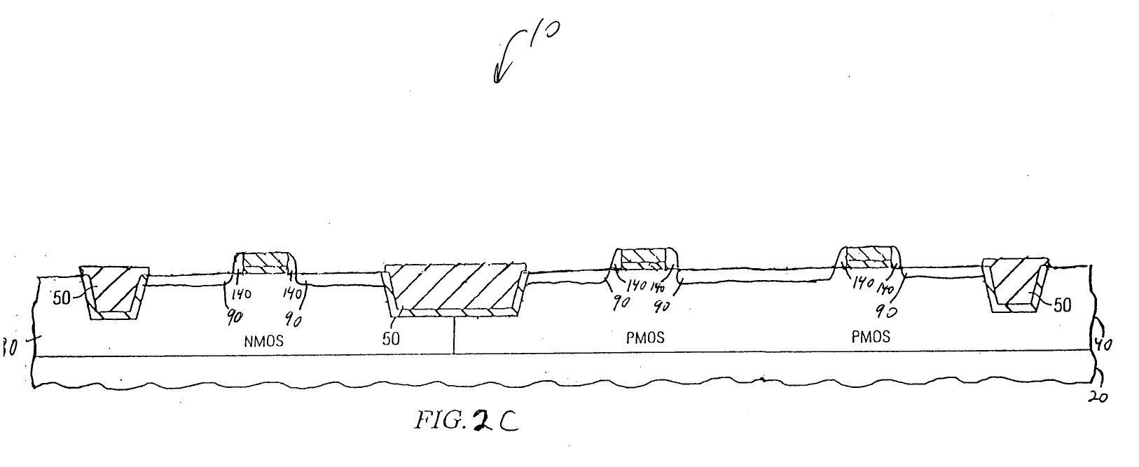

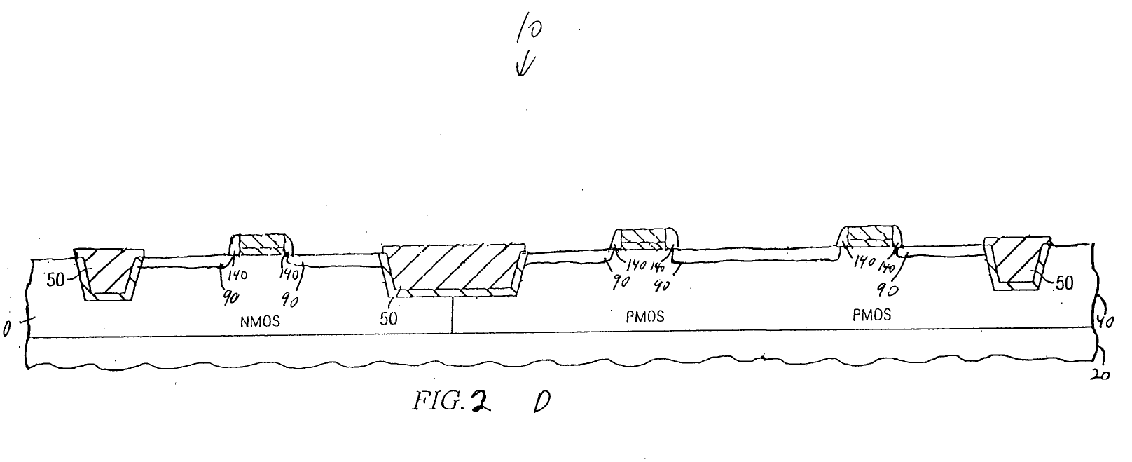

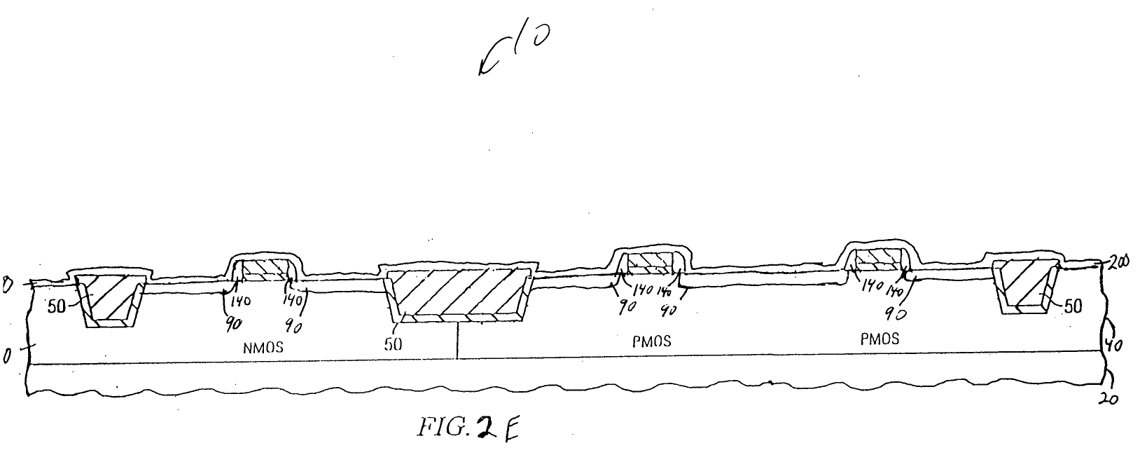

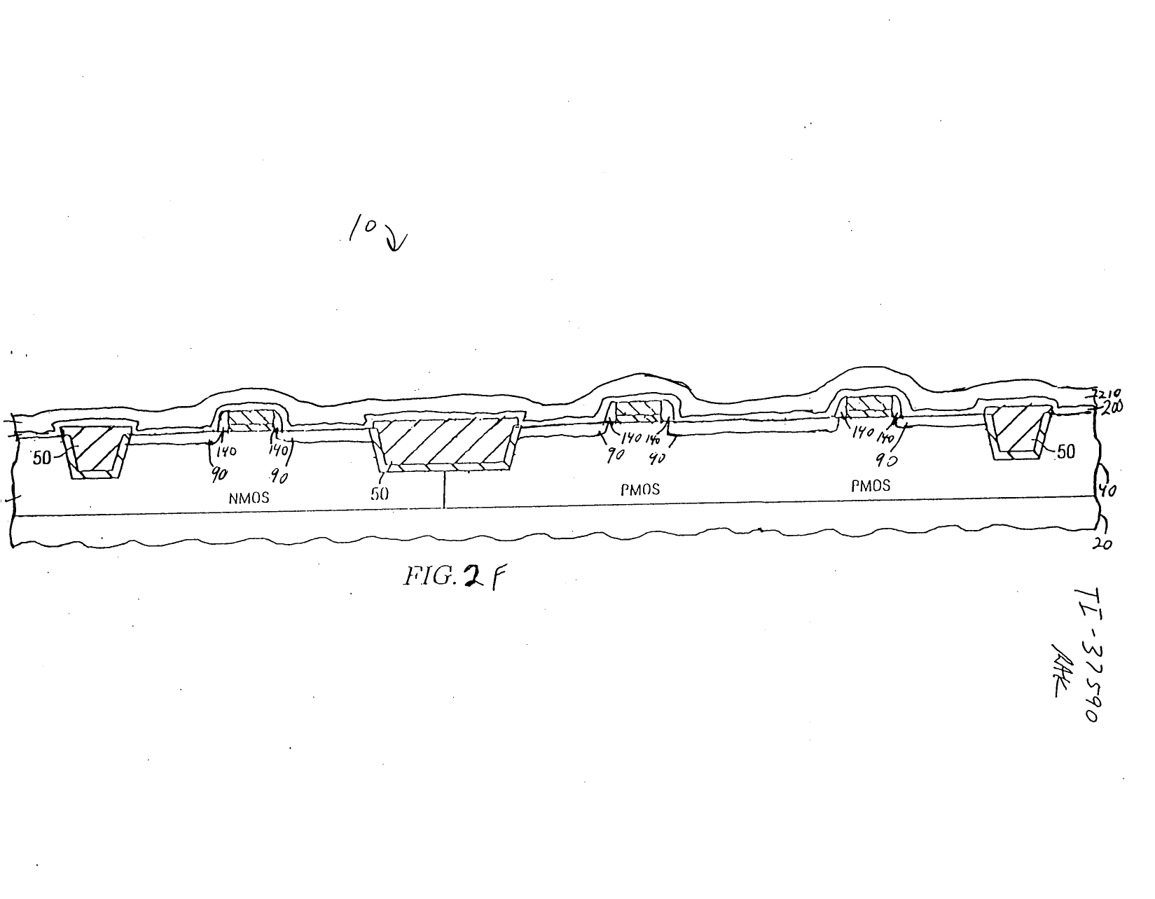

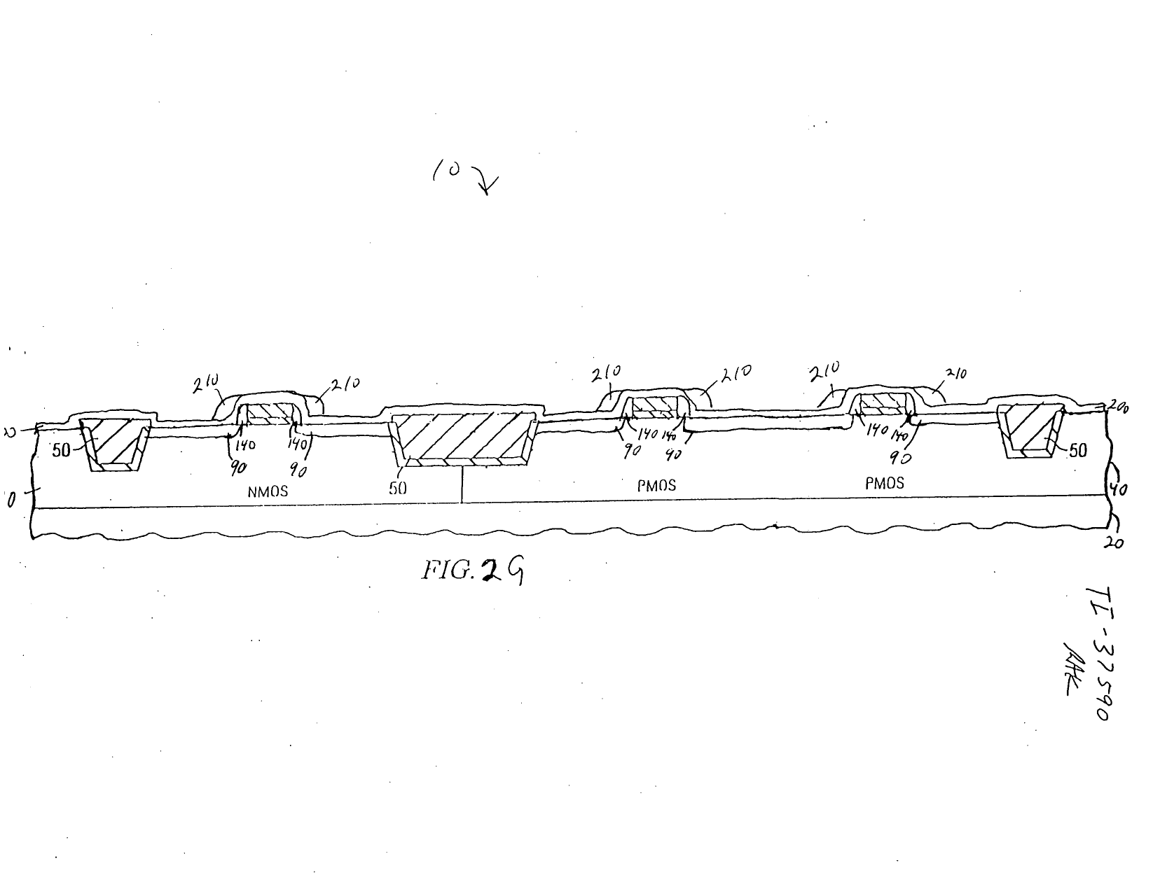

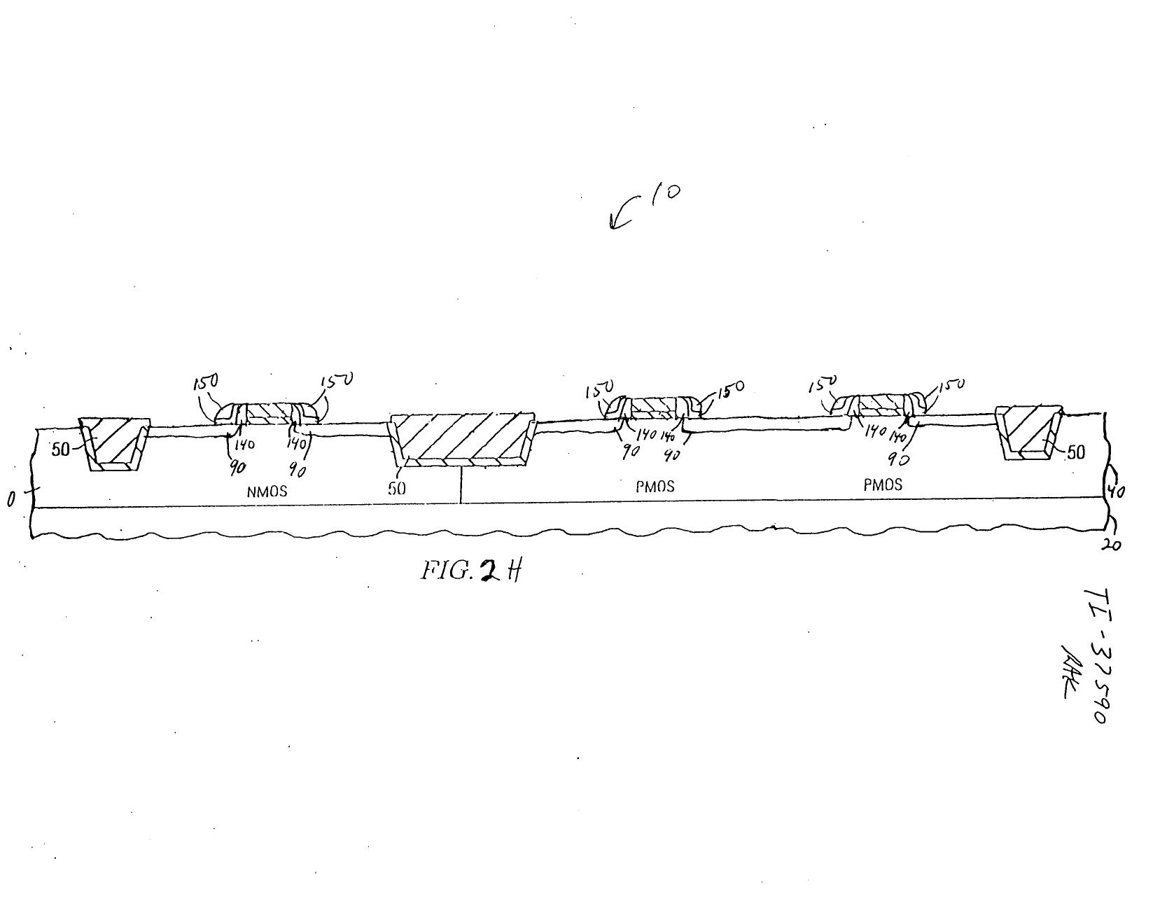

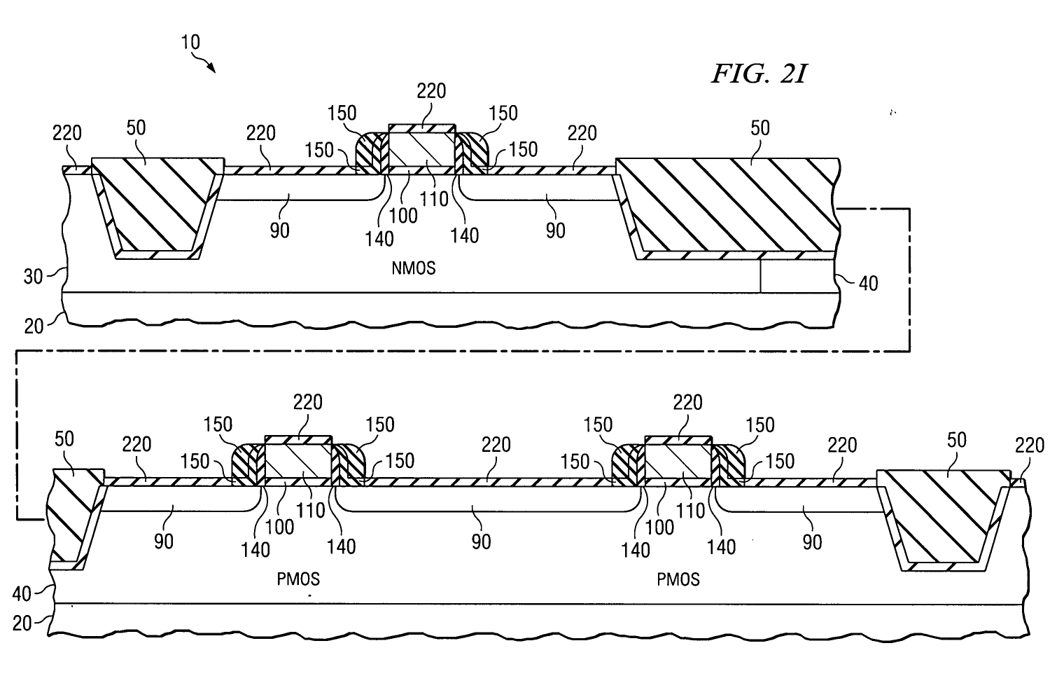

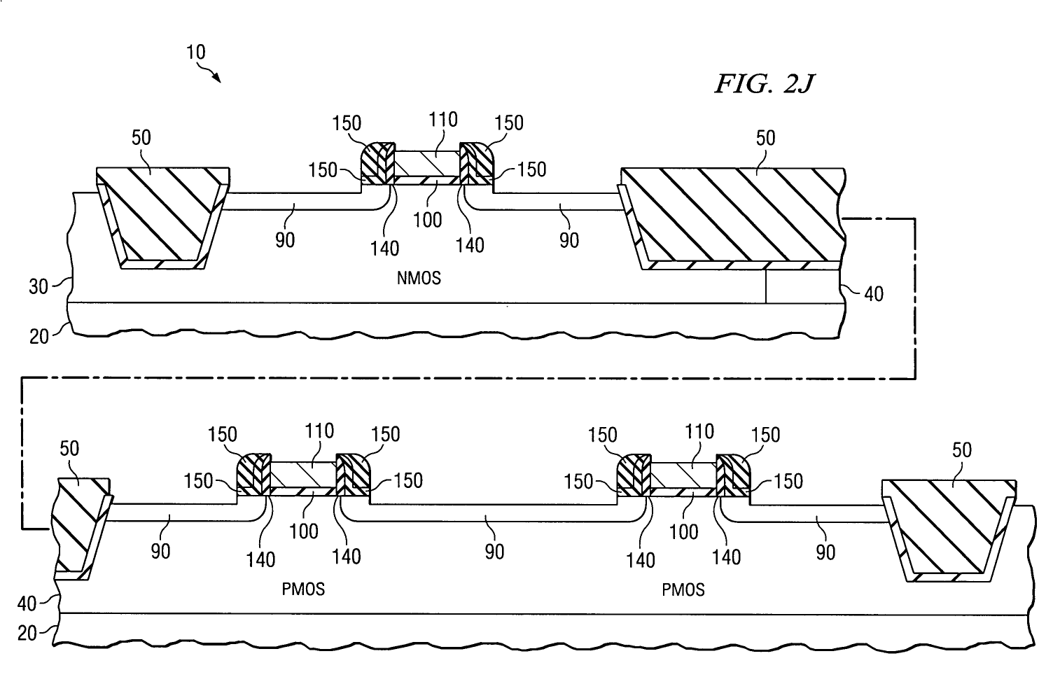

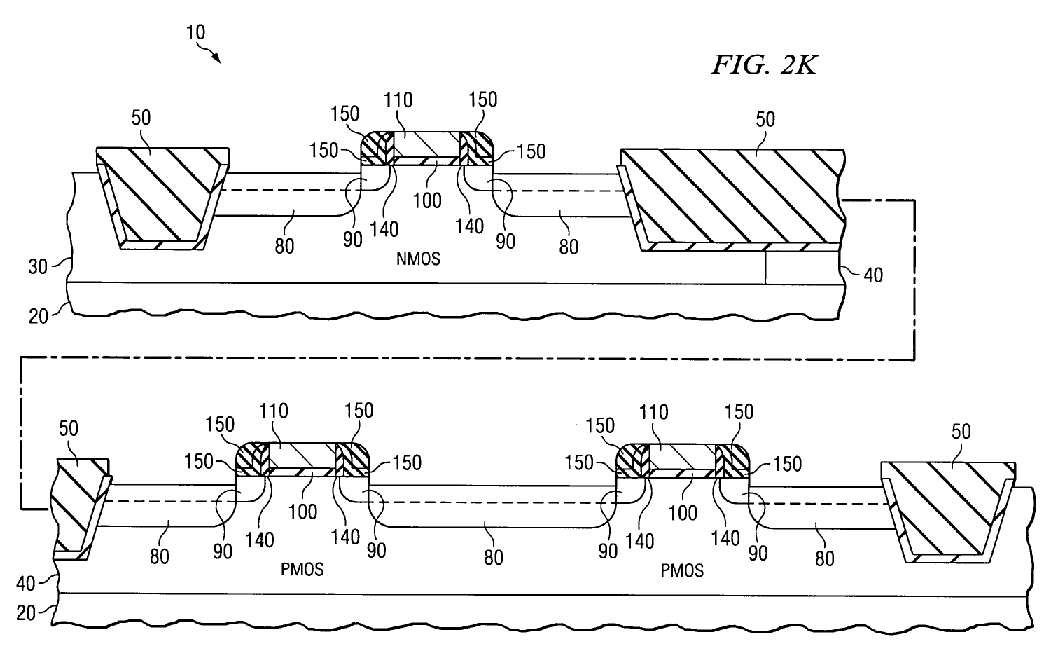

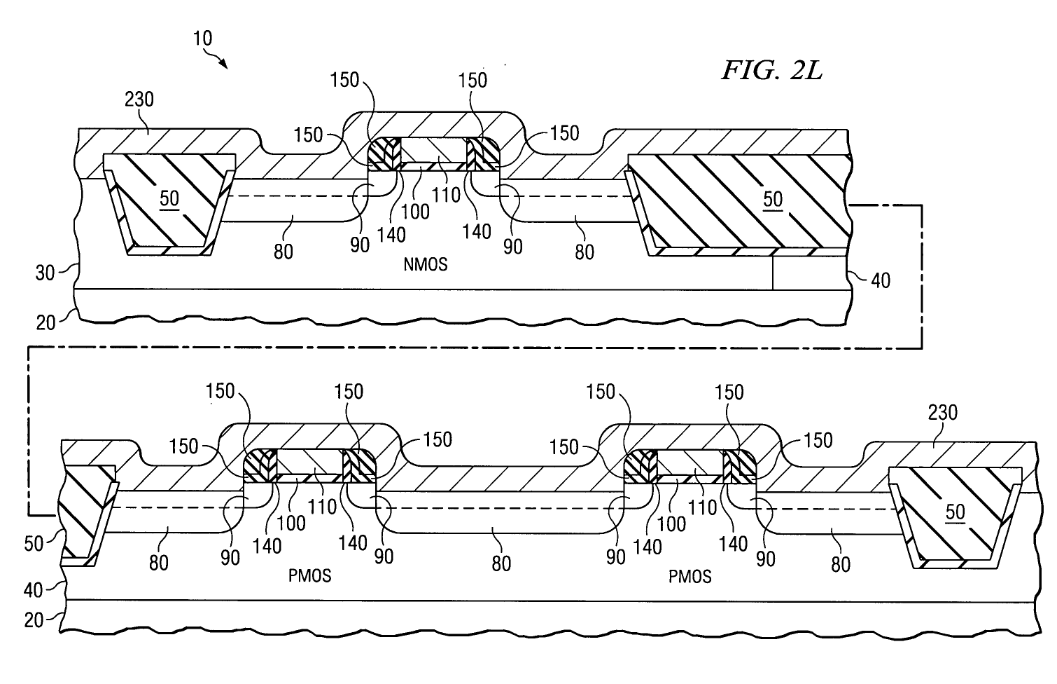

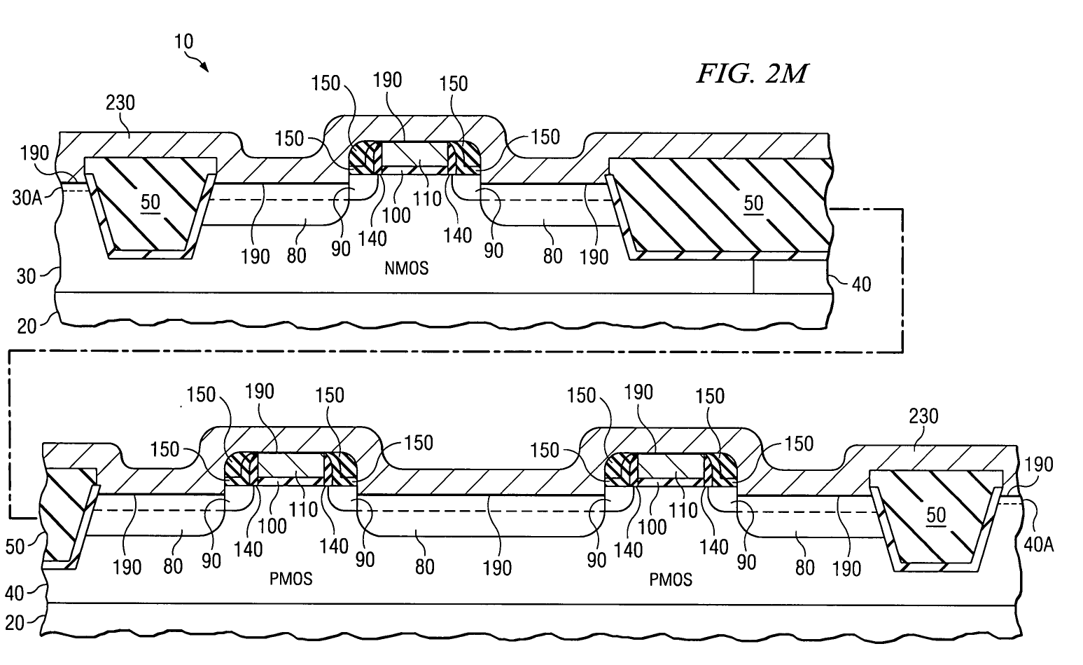

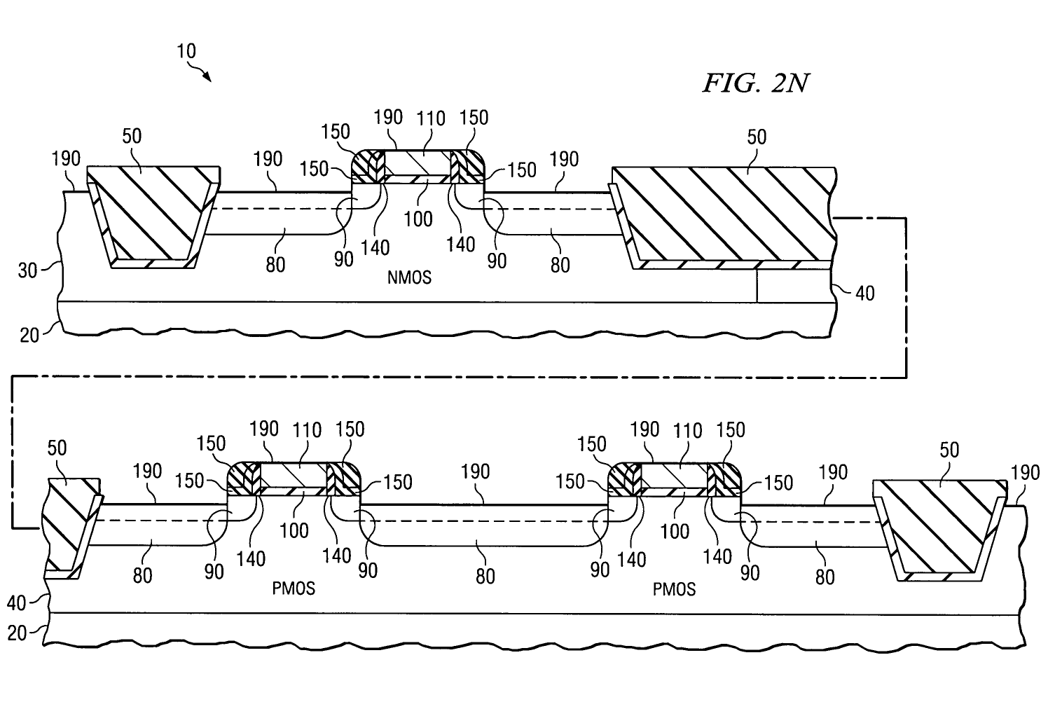

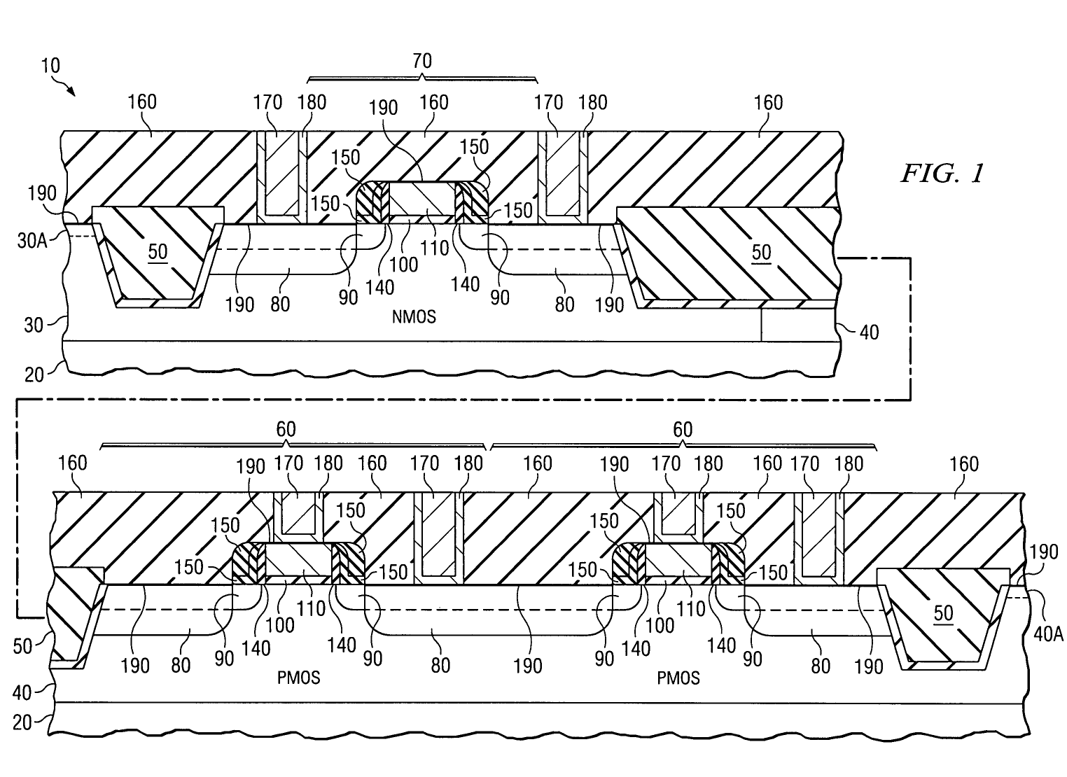

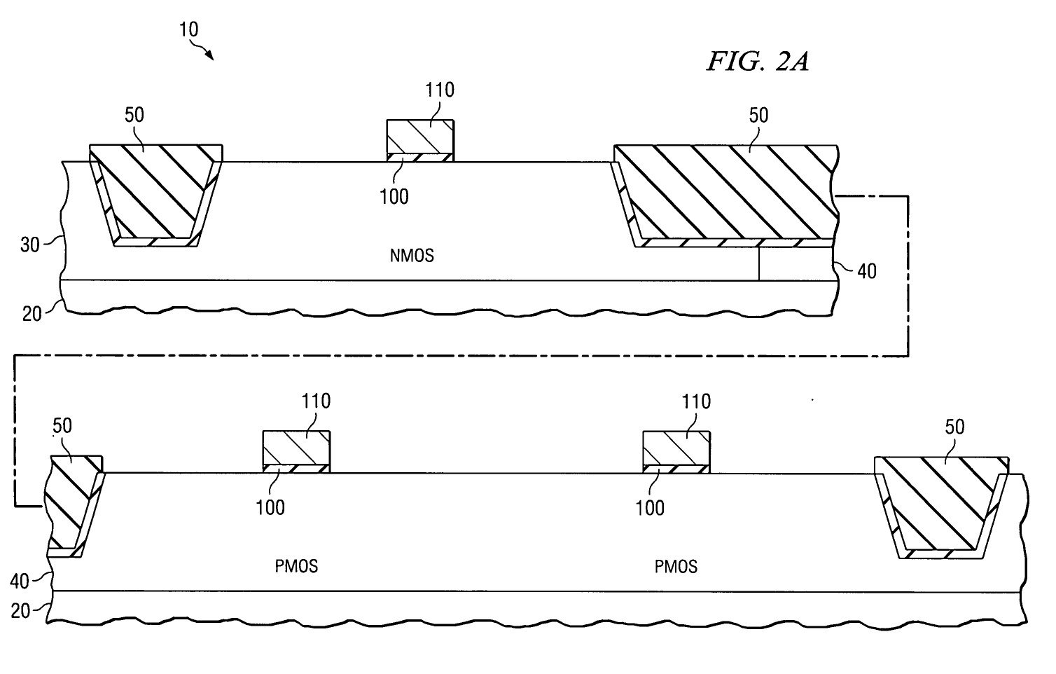

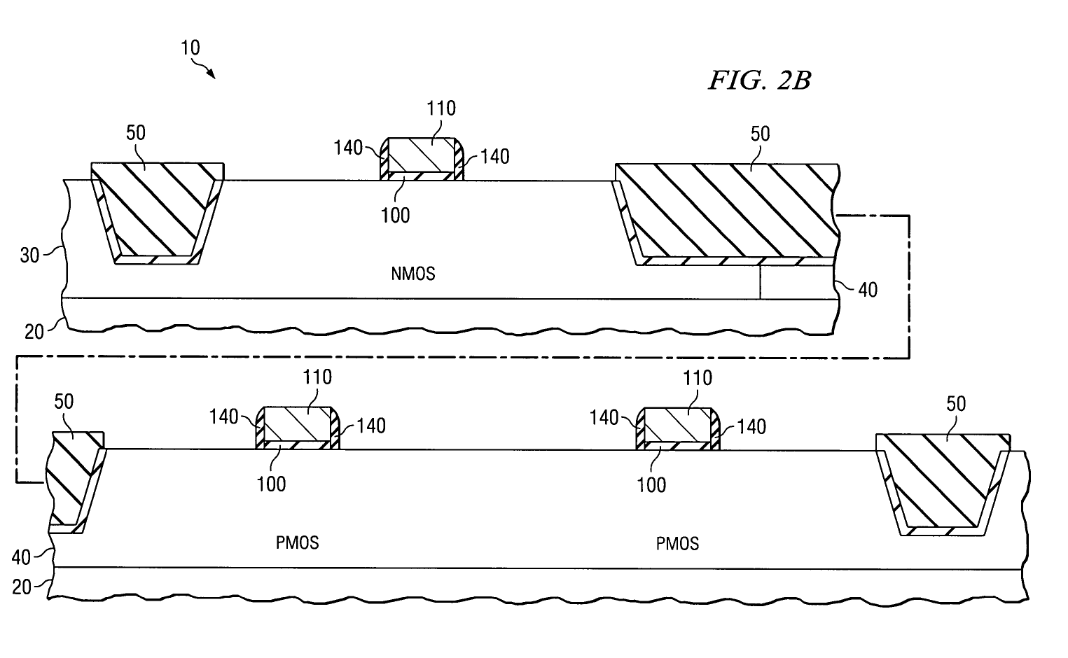

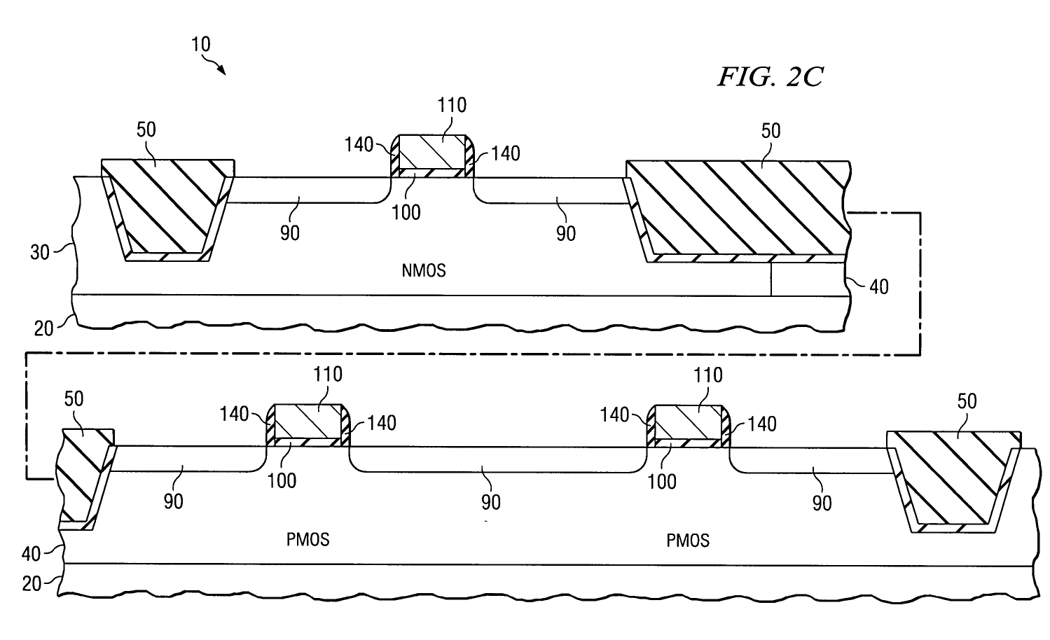

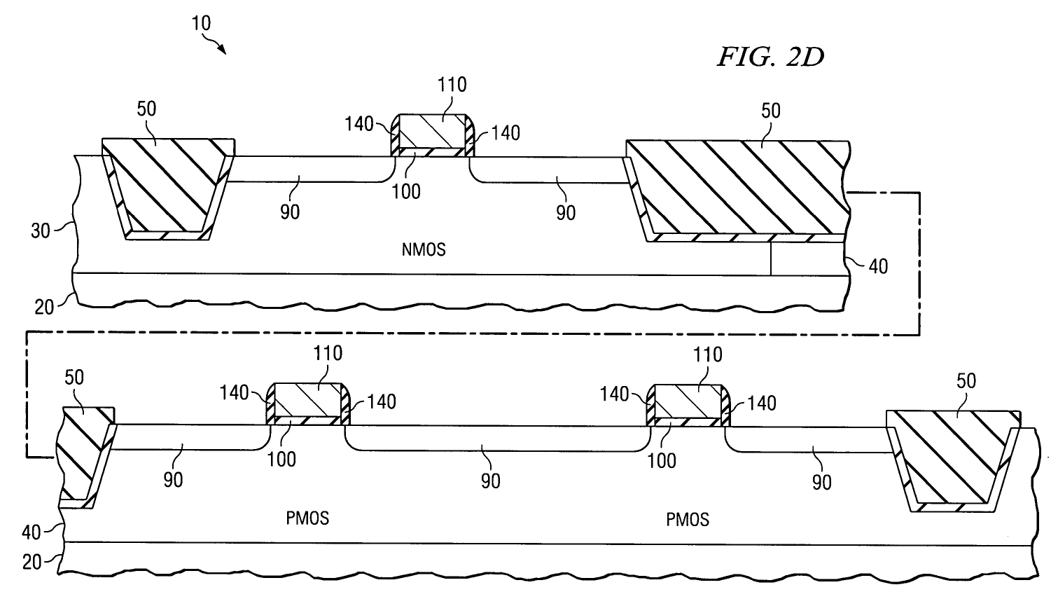

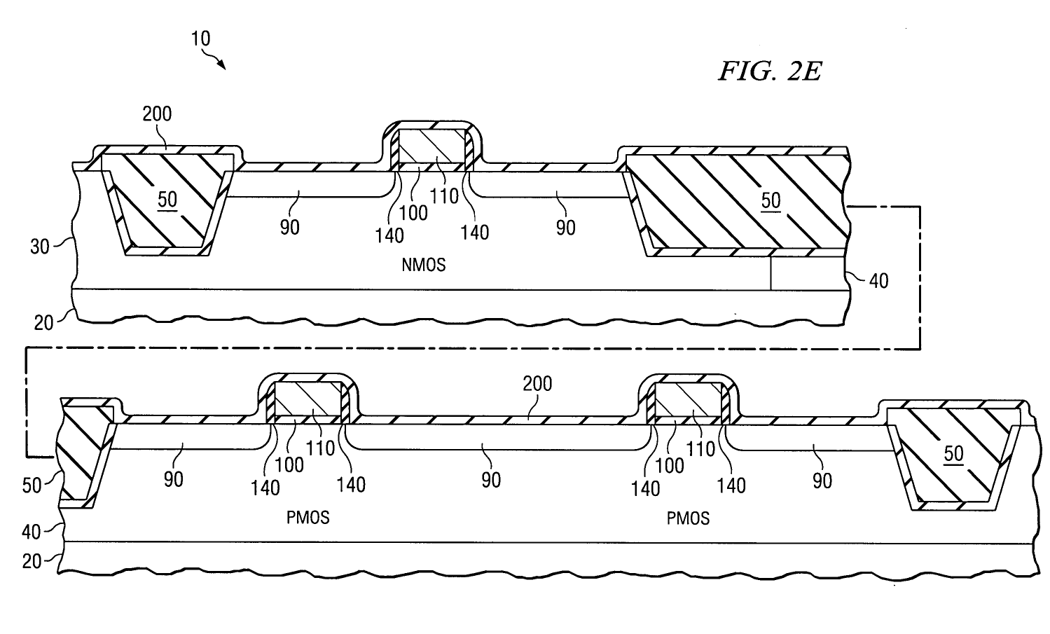

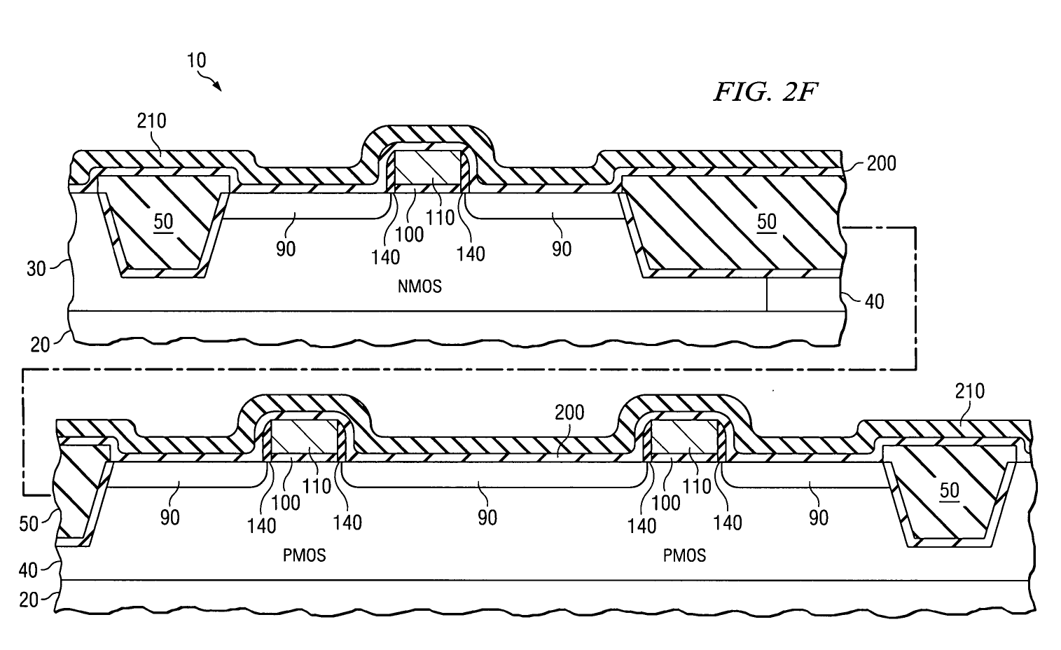

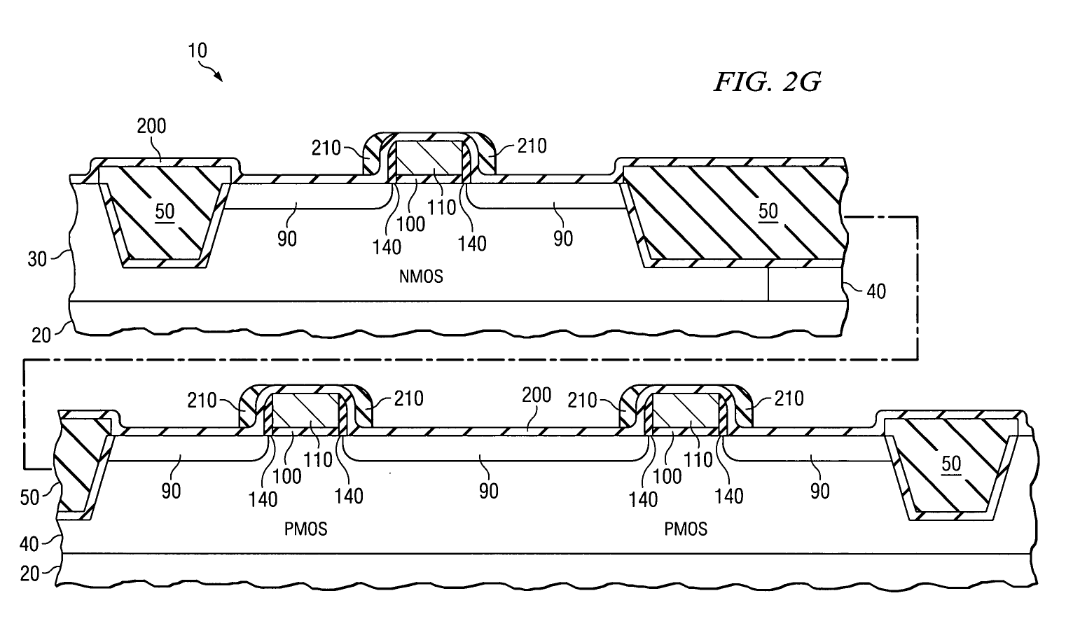

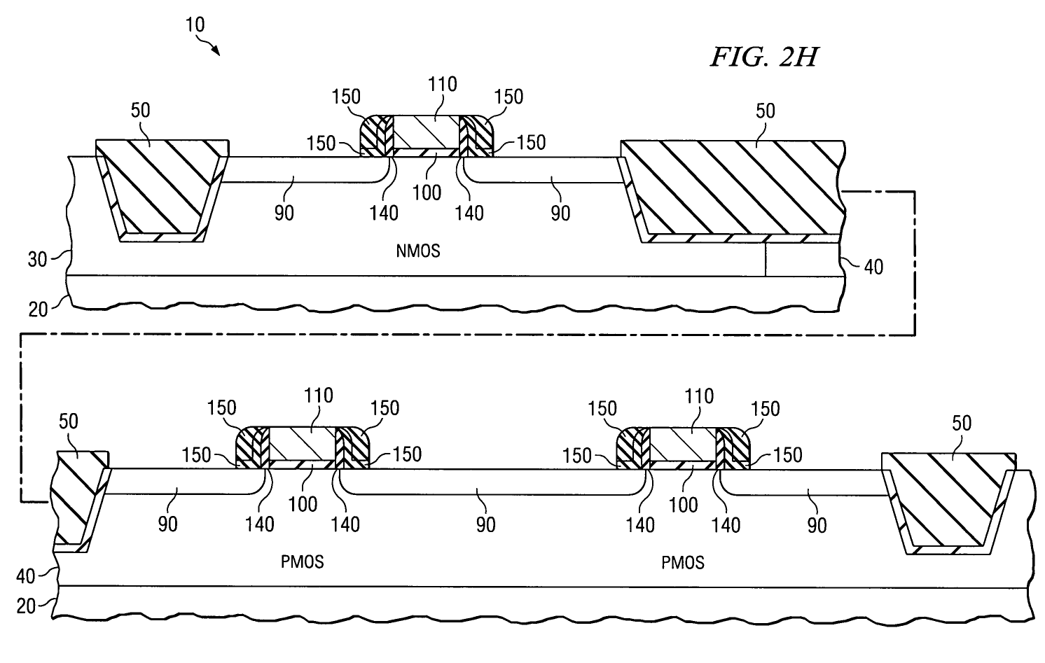

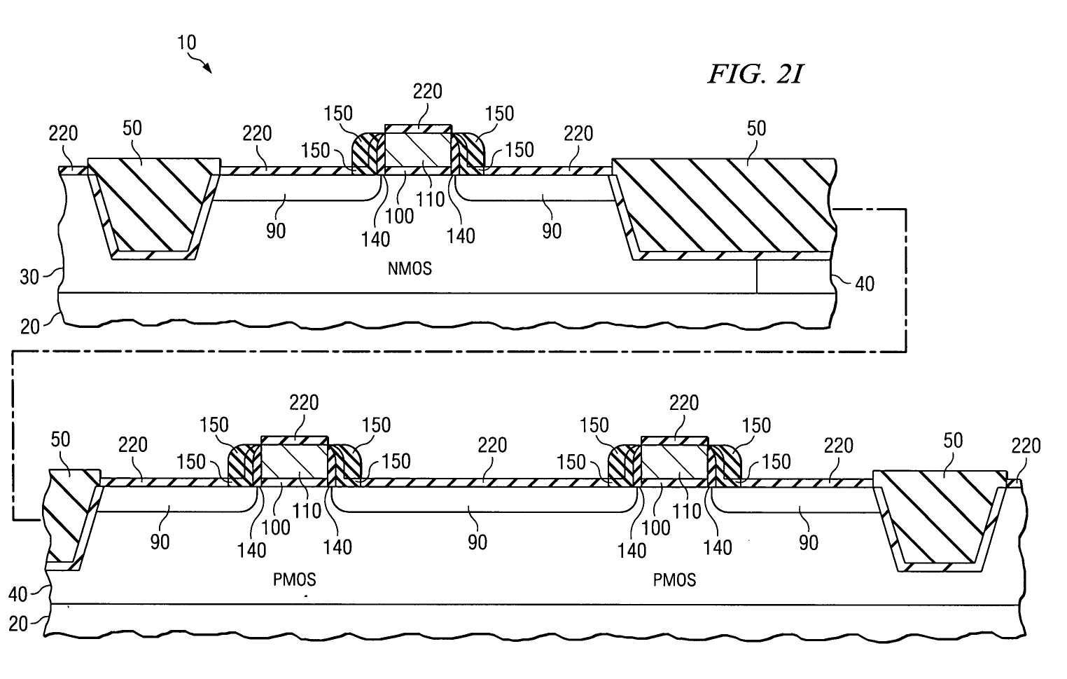

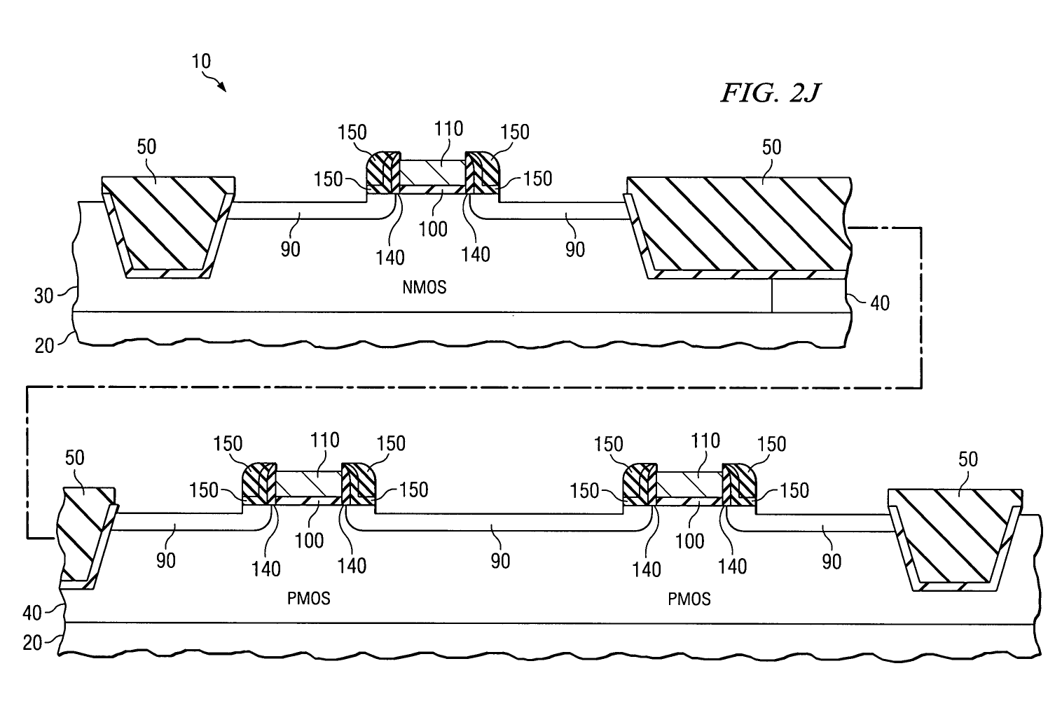

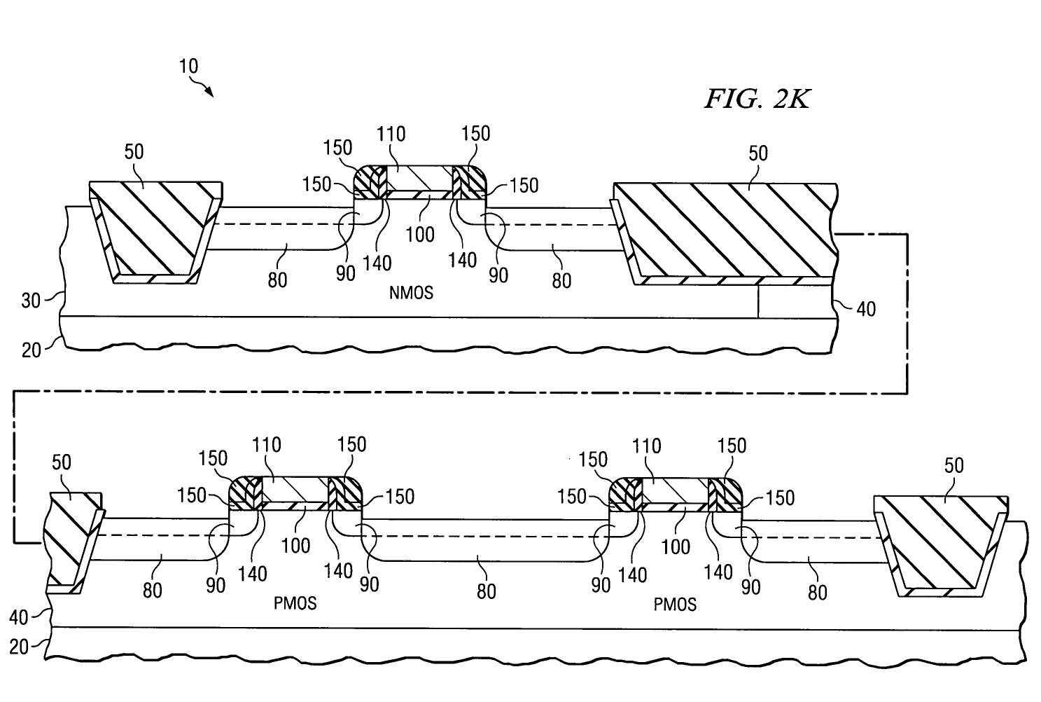

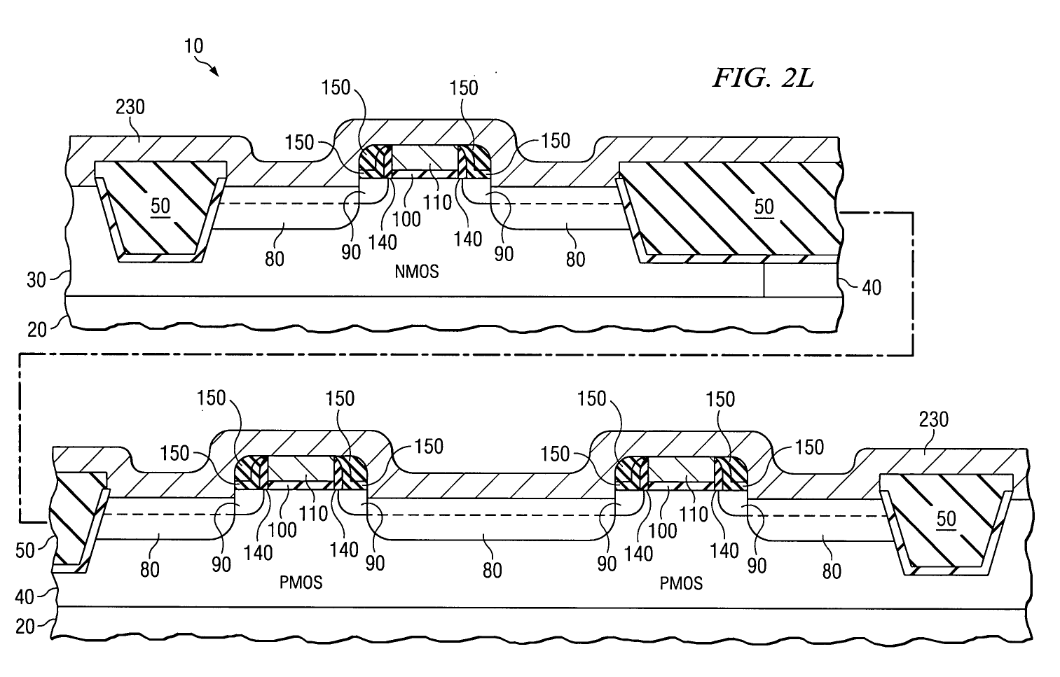

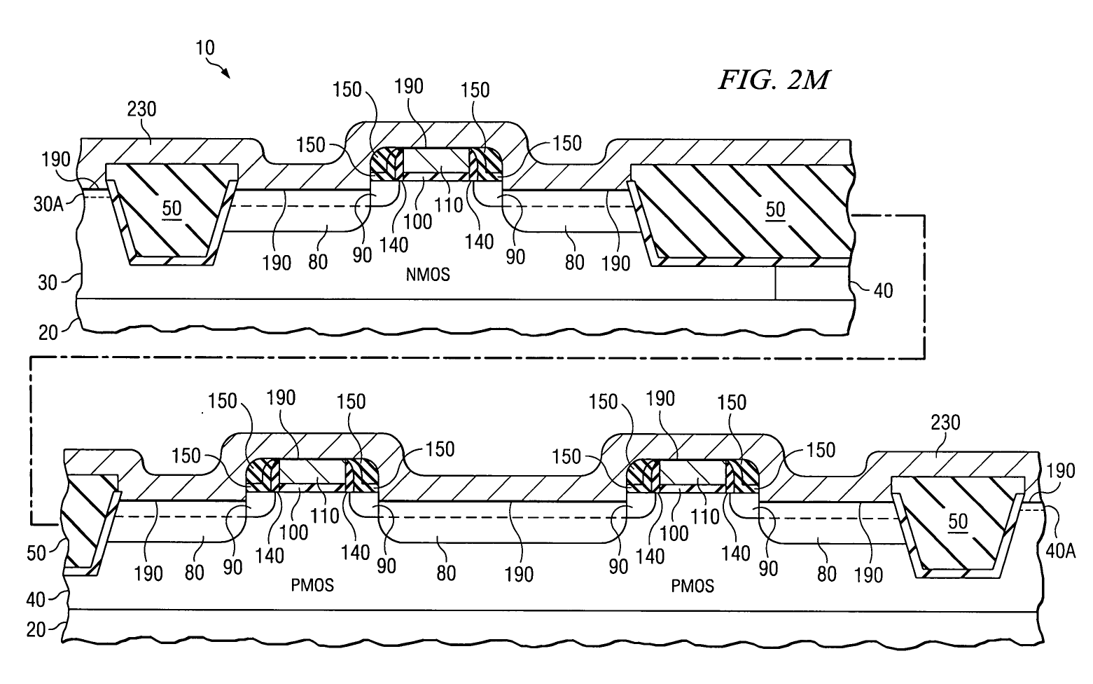

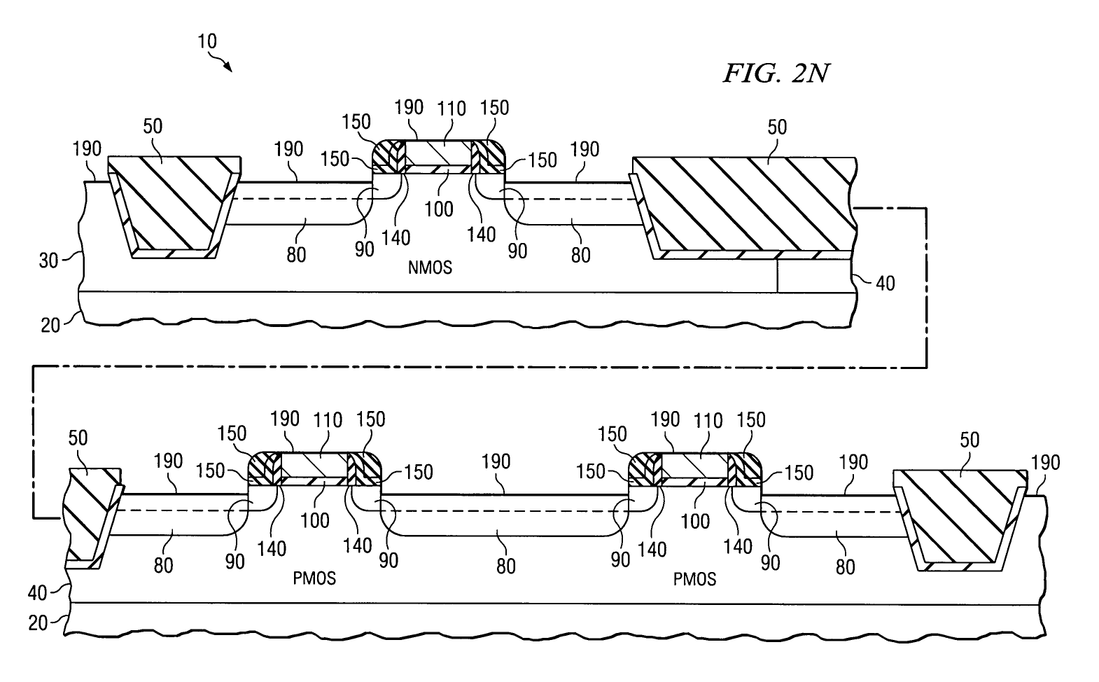

Referring again to the drawings, FIGS. 2A-2N are cross-sectional views of a partially fabricated semiconductor wafer illustrating a process for forming an improved suicide 190 in accordance with one embodiment of the present invention. FIG. 2A is a cross-sectional view of the semiconductor wafer 10 after the formation of the p-wells 30, n-wells 40, shallow trench isolation structures 50, and the gate stack 100, 110 on the top surface of a semiconductor substrate 20. The fabrication processes used to form the semiconductor wafer 10 shown in FIG. 2A are those that are standard in the industry.

In the example application, the semiconductor substrate 20 is silicon; however any suitable material such as germanium or gallium arsenide may be used. The example gate dielectric layer 100 is silicon dioxide formed with a thermal oxidation process. However, the gate dielectric layer 100 may be any suitable material, such as nitrided silicon oxide, silicon nitride, or a high-k gate dielectric material, and may be formed using any one of a variety of processes such as an oxidation process or thermal nitridation.

The gate electrode layer 110 is comprised of polycrystalline silicon in the example application. However, it is within the scope of the invention to use other materials such as an amorphous silicon, a silicon alloy, or other suitable materials. The gate electrode 115 may be formed using any process technique such as chemical vapor deposition (“CVD”) or physical vapor deposition (“PVD”).

The gate stack may be created through a variety of processes. For example, the gate stack may be created by forming a layer of photoresist over the semiconductor wafer, patterning the photoresist, and then using the photoresist pattern to etch the layer of oxide 100 and the layer of polysilicon 110. The gate stack may be etched using an suitable etch process, such as an anisotropic etch.

Generally, the next step in the fabrication of the transistors 60, 70 is the formation of the extension regions 90. As shown in FIG. 2B, extension sidewalls 140 are formed on the outer surface of the gate stack 100, 110. The extension sidewalls 140 may be comprised of an oxide, oxi-nitride, silicon dioxide, nitride, or any other dielectric material or layers of dielectric materials. Furthermore, the extension sidewalls 140 may be formed with any suitable process, such as thermal oxidation, deposited oxide, CVD, or PVD.

These extension sidewalls 140 are now used as a template to facilitate the proper placement of the extension regions 90, as shown in FIG. 2C. However, it is within the scope of the invention to form the extension regions 90 at any point in the manufacturing process.

The extension regions 90 are formed near the top surface of the semiconductor substrate 40 using any standard process. For example, the extension regions 90 may be formed by low-energy ion implantation, a gas phase diffusion, or a solid phase diffusion. The dopants used to create the extension regions 90 for a PMOS transistor 60 are p-type (i.e. boron). The dopants used to create the extension regions 90 for a NMOS transistor 70 are n-type (i.e. phosphorous or arsenic). However, other dopants or combinations of dopants may be used to form the source/drain extension regions 90.

In the example application shown in FIG. 2C, the extension sidewall spacers 140 are used to direct the dopant implantation to the proper location 90 within the semiconductor substrate 40. Thus, the source and drain extension regions 90 initiate from points in the semiconductor substrate 40 that are approximately at the outer corner of the extension sidewalls 140.

At some point after the implantation of the source/drain extension regions 90, the extensions 90 are activated by an anneal process (performed now or later). This anneal step may be performed with any suitable process such as rapid thermal anneal (“RTA”). The source/drain extension anneal will likely cause a lateral migration of each extension region toward the opposing extension region, as shown in FIG. 2D.

Next, the source/drain sidewall spacers 150 are formed proximate to the extension sidewall spacers 140. The source/drain sidewall spacers 150 may be formed using any standard process. In the example application, the source/drain sidewall spacers 150 are comprised of a cap oxide layer and a silicon nitride layer that are formed with a CVD process and subsequently anisotropically etched. However, it is within the scope of the invention to use more layers (i.e. a spacer oxide layer, a silicon nitride layer, and a final oxide layer) or less layers (i.e. just an oxide layer or a nitride layer) to create the source/drain sidewall spacers 150.

Referring to FIG. 2E, the first step in the formation of the example source/drain sidewall spacers 150 is the deposition of the cap oxide layer 200. The cap oxide layer 200 may be deposited by any suitable process such as CVD. Next, as shown in FIG. 2F, the silicon nitride layer 210 is deposited. The silicon nitride layer 210 may also be deposited by any suitable process such as CVD.

The source/drain sidewall layers 200 and 210 are now etch to create the source/drain sidewall spacers 150. In the example application, the source/drain sidewall layers 200 and 210 are etched with a standard anisotropic plasma etch. This etch may be performed using any suitable machine such as the ER27 (made by Applied Materials). As shown in FIG. 2G, the silicon nitride layer 210 is etched first, using suitable anisotropic etch chemistry such as CF₄. Then, as shown in FIG. 2H, the cap oxide layer 200 is etched (generally in the same ER27 etch machine) using any suitable anisotropic etch chemistry such as CF₄+Ar. The formation of the source/drain sidewall spacers 150 is now complete and the semiconductor wafer 10 is subjected to a standard post-etch cleaning process (i.e. using a FSI Mercury machine with a wet chemistry of Piranha+SC1).

It is believed that the anisotropic plasma etch process that is used to form the source/drain sidewall spacers 150 leaves particles of contamination (i.e. carbon and nitrogen residue) on the surface of the semiconductor wafer 10. It is also believed that the concentration of contamination is greatest in surface locations that are closest to the source/drain sidewall spacers 150. Some of this contamination will become physically pushed into the semiconductor substrate 30, 40 during the subsequent source/drain implant process. In addition, some of the contamination will act as micro-masks—blocking the proper implantation of dopants during the source/drain implant process. Moreover, the contamination will interfere with the silicidation process (described below), resulting in no silicide or less than optimum and non-uniform silicide layers over the active silicon areas (i.e. the exposed portions of the substrate 30, 40).

Therefore, in accordance with the invention, the semiconductor wafer 10 is subjected to an oxidation process and a wet clean prior to the source/drain implant process (which is generally the next fabrication step). As shown in FIG. 21, the thermal oxidation process will consume a small portion of the top layer of active silicon oxide while growing the oxide layer 220. As an example, about 5-25 Å of the active silicon surface 30, 40 will be consumed (in addition to the surface of the gate polysilicon 110) and the resulting oxidation layer 220 will be approximately 10-50 Å thick.

In the best mode application, a furnace thermal oxidation process is performed to create the oxidation layer 220, using a standard TEL machine (made by Applied Materials). However, it is within the scope of the invention to use other processes to create the oxidation layer 220, such as a Rapid Thermal Oxidation process.

The furnace thermal oxidation process is performed using a temperature range of 700-1000° C. and an O₂/N₂ chemistry for 30 minutes in order to grow an oxide layer 220 that is approximately 10-50 Å thick. In the best mode application, the furnace thermal oxidation process is performed at a temperature of approximately 800° C. (with a lower O₂/N₂ flow ratio) in order to grow an oxide layer 220 that is approximately 25 Å thick. The thermal oxidation process will likely cause some of the contamination (i.e. carbon) to outgas. In addition, the thermal oxidation process will oxidize active silicon around and underneath the residues. Therefore, the remaining contamination on the silicon surface post source/drain sidewall spacer etch will be enveloped by the grown oxide layer 220.

It is within the scope of the invention to use this thermal oxidation process (using an oxidizing ambient at a high temperature) to also activate the extension regions 90. This alternative process flow could save manufacturing time and manufacturing costs by eliminating the need for the extension anneal step discussed above (FIG. 2D).

As shown in FIG. 2J, the oxidation layer 220 (now containing embedded contamination) is striped using a wet clean process. In the best mode application, the oxidation layer 220 is removed with a two step wet clean process: a Hot SC1 (“HTSC1”) clean followed by a short HF deglaze. More specifically, a standard HTSC1 clean is first performed by dunking the semiconductor wafer 10 in a tank, such as the SH11D. This clean is performed in a high temperature bath (i.e. 65° C.). Next, a mild HF based wet strip (called a “HF deglaze”) is performed. The HF deglaze is generally performed in a separate tank.

However, it is within the scope of the invention to remove the oxide 220 by any suitable cleaning process. For example, the oxide 220 may be removed by a HF deglaze only, a HTSC1 clean only, or any other stripping process that won't damage the underlying semiconductor substrate 20, 30, 40.

It is to be noted that the active silicon surfaces of the semiconductor substrate 30, 40 are now lower (i.e. regions 30 and 40 are not as thick—see FIG. 2J) because a portion of the surface layer was consumed by the preceding thermal oxidation process. Most, if not all, of the contamination on (and within) the active silicon areas of the semiconductor wafer 10 following the etch of the source/drain sidewall spacers 150 is now removed.

The fabrication of the semiconductor wafer 10 now continues using standard manufacturing processes. For example, the next step is to use the source/drain sidewall spacers 150 as a template for the implantation of dopants into the source and drain regions.

The source and drain regions 80, shown in FIG. 2K, may be formed through any one of a variety of processes, such as deep ion implantation or deep diffusion. The dopants used to create the source and drain regions 80 for PMOS transistors are typically boron and for NMOS transistors are typically arsenic; however, other dopants or combinations for dopants may be used.

The implantation of the dopants is self-aligned with respect to the outer edges of the source/drain sidewalls 150. However, it is to be noted that due to lateral straggling of the implanted species, the source/drain regions 80—as well as the extension regions 90—initiate slightly inside the outer corner of the sidewalls 140, 150 respectively.

In the example application, the source/drain regions 80 are activated by a source/drain anneal step. This anneal step acts to repair the damage to the semiconductor wafer and to activate the dopants. The activation anneal may be performed by any technique such as Rapid Thermal Anneal (“RTA”), flash lamp annealing (“FLA”), or laser annealing. This anneal step often causes lateral and vertical migration of dopants in the extension regions 90 and the source/drain regions 80.

Generally, the next step in the manufacturing process is the performance of the silicide loop. The purpose of the silicide loop is the creation of silicide 190 on the surface of the active silicon 30, 40 and gate polysilicon 110 (see FIG. 1). Referring to FIG. 2L, the first step of the silicide loop is the deposition of an interface layer 230 over the top surface of the semiconductor wafer 10. The interface layer 230 is preferably comprised of Co; however, other suitable materials such as Ni may be used.

An optional capping layer (not shown) may also be formed over the interface layer 230. If used, the capping layer acts as a passivation layer that prevents the diffusion of oxygen from ambient into the interface layer 230. The capping layer may be any suitable material, such as TiN.

The second step of the silicide loop is an anneal. The semiconductor wafer 10 may be annealed with any suitable process, such as RTA. This anneal process will cause a silicide 190 (i.e. a Co-rich silicide or Co mono-silicide) to form over all active surfaces that are in contact with the interface layer 230; namely, at the surface of the source/drain 80, the surface of the well regions 30, 40, and the surface of the gate electrodes 110. These silicide regions 190 are shown in FIG. 2M.

It is to be noted that the interface layer 230 will only react with the active substrate (i.e. exposed Si); namely, the source/drain 80, the gate electrode 110, and the unmodified surfaces of well regions 30, 40. Therefore, the silicide 190 formed by this annealing process is considered a self-aligned silicide (“salicide”).

The third step in the silicide loop is the removal of the un-reacted interface layer 230 (as well as the underlying oxide or nitride), as shown in FIG. 2N. The un-reacted interface layer 230 (and the capping layer, if used) are removed using any suitable process such as a wet etch process (i.e. using a fluid mixture of sulfuric acid, hydrogen peroxide, and water).

The fourth step of the silicide loop is to perform a second anneal (such as a RTA) to further react the silicide 190 with the exposed surfaces of well regions 30, 40, the gate electrode 110, and the sources and drains 80. If the initial anneal process of the silicide loop did not complete the silicidation process, this second anneal will ensure the formation of a mono-silicide CoSi₂—which lowers the sheet resistance of the silicide 190.

The oxidation and wet clean processes performed after the completion of the source/drain sidewall spacers facilitated the removal of the undesirable contamination which was present on the surface of the semiconductor wafer 10 at that stage of the fabrication process. As a result, the silicide 190 at this stage in the fabrication process is well formed and has better silicide thickness uniformity than it would if the present invention was not implemented.

Generally, the next step is the formation of the dielectric layer. Referring to FIG. 1, the dielectric insulator layer 160 may be formed using plasma-enhanced chemical vapor deposition (“PECVD”) or another suitable process. The dielectric insulator 160 may be comprised of any suitable material such as SiO₂ or OSG.

The contacts 170 are formed by etching the dielectric insulator layer 160 to expose the desired gate, source and/or drain location. An example etch process for creating the contact holes is an anisotropic etch. The etched holes are usually filled with a liner 180 before forming the contacts 170 in order to improve the electrical interface between the silicide 190 and the contact 170. Then the contacts 170 are formed within the liner 180; creating the initial portion of the electrical interconnections from the transistors 60, 70 to various semiconductor components (not shown) located within the semiconductor substrate 20.

The fabrication of the final integrated circuit continues with the fabrication of the back-end structure. As discussed above, the back-end structure contains the metal interconnect layers of the integrated circuit. Once the fabrication process is complete, the integrated circuit will be tested and packaged.

Various additional modifications to the invention as described above are within the scope of the claimed invention. As an example, additional interfacial layers may be formed between any of the layers shown. Similarly, any of the sidewall layers described in the example application may be omitted. For example, the extension sidewalls 140 may be omitted without departing from the scope of the invention. Moreover, if extension sidewalls 140 are omitted than the thickness of source/drain sidewalls 150 may be increased.

It is to be noted that an anneal process may be performed after any step in the above-described fabrication process. When used, the anneal process can improve the microstructure of materials and thereby improve the quality of the semiconductor structure.

This invention may be implemented in a sidewall spacer structure that is comprised of different materials or layers than is described above. In addition, the suicides may be comprised of other materials such as titanium, tungsten, tantalum, or other conventional silicide materials or combinations of silicide materials. Furthermore, this invention may be implemented in other semiconductor structures such as capacitors or diodes, and also in different transistor structures such as biCMOS and bipolar transistors.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method for improving silicide uniformity over active silicon areas of a semiconductor wafer, comprising:
performing a source/drain sidewall spacer etch;
performing an oxidation process; and
performing a wet clean.

2. The method of claim 1 further comprising:
implanting source and drain regions;
annealing said semiconductor wafer to create sources and drains; and
performing a silicide loop to form a silicide within a top surface of said active silicon areas.

3. The method of claim 1 wherein said step of performing a source/drain sidewall spacer etch comprises;
plasma etching a silicon nitride layer;
plasma etching a cap oxide layer; and
performing a post-etch plasma clean.

4. The method of claim 1 wherein said step of performing an oxidation process comprises a Rapid Thermal Oxidation at a temperature range of 700-1000° C. to grow approximately 10-50 Å of oxide on said active silicon areas.

5. The method of claim 1 wherein said step of performing an oxidation process comprises a furnace thermal oxidation at a temperature range of 700-1000° C. to grow approximately 10-50 Å of oxide on said active silicon areas.

6. The method of claim 5 wherein said furnace thermal oxidation step is performed at a temperature of approximately 800° C. to grow approximately 25 Å of said oxide.

7. The method of claim 1 wherein said step of performing a wet clean comprises a HF deglaze.

8. The method of claim 1 wherein said step of performing a wet clean comprises a Hot SC1 clean.

9. The method of claim 1 wherein said step of performing a wet clean comprises a HTSC1 process followed by a HF deglaze.

10. The method of claim 9 wherein said HTSC1 process is performed at a temperature of approximately 65° C.

11. The method of claim 1 wherein said step of performing an oxidation process is a substitute for a source/drain extension anneal of said semiconductor wafer.

12. The method of claim 2 wherein said silicide is a self-aligned silicide.

13. The method of claim 2 wherein said silicide loop comprises:
forming an interface layer over said semiconductor wafer;
performing a first anneal to create said silicide;
removing an un-reacted portion of said interface layer; and
performing a second anneal.

14. The method of claim 13 wherein said interface layer comprises Co.

15. The method of claim 13 wherein said interface layer comprises Ni.

16. A method for improving suicide uniformity over active silicon areas of a semiconductor wafer, comprising:
performing a source/drain sidewall spacer etch;
performing an oxidation process;
performing a wet clean;
implanting source and drain regions;
annealing said semiconductor wafer to create sources and drains; and
performing a silicide loop to form a silicide within a top surface of said active silicon areas.

17. The method of claim 16 wherein said step of performing a source/drain sidewall spacer etch comprises;
plasma etching a silicon nitride layer;
plasma etching a cap oxide layer; and
performing a post-etch plasma clean.

18. The method of claim 16 wherein said step of performing an oxidation process comprises a Rapid Thermal Oxidation at a temperature range of 700-1000° C. to grow approximately 10-50 Å of oxide on said active silicon areas.

19. The method of claim 16 wherein said step of performing an oxidation process comprises a furnace thermal oxidation at a temperature range of 700-1000° C. to grow approximately 10-50 Å of oxide on said active silicon areas.

20. The method of claim 19 wherein said furnace thermal oxidation step is performed at a temperature of approximately 800° C. to grow approximately 25 Å of said oxide.

21. The method of claim 16 wherein said step of performing a wet clean comprises a HF deglaze.

22. The method of claim 16 wherein said step of performing a wet clean comprises a HTSC1 process.

23. The method of claim 16 wherein said step of performing a wet clean comprises a HTSC1 process followed by a HF deglaze.

24. The method of claim 23 wherein said HTSC1 process is performed at a temperature of approximately 65° C.

25. The method of claim 16 wherein said step of performing an oxidation process is a substitute for a source/drain extension anneal of said semiconductor wafer.

26. The method of claim 16 wherein said silicide is a self-aligned silicide.

27. The method of claim 16 wherein said silicide loop comprises:
forming an interface layer over said semiconductor wafer;
performing a first anneal to create said silicide;
removing an un-reacted portion of said interface layer; and
performing a second anneal.

28. The method of claim 27 wherein said interface layer comprises Co.

29. The method of claim 27 wherein said interface layer comprises Ni.

30. A method for improving silicide uniformity over active silicon areas of a semiconductor wafer, comprising:
plasma etching a silicon nitride layer;
plasma etching a cap oxide layer; and
performing a post-etch plasma clean;
performing a furnace thermal oxidation process at a temperature of approximately 800° C. to grow approximately 25 Å of oxide;
performing a HTSC1 process followed by a HF deglaze;
implanting source and drain regions;
annealing said semiconductor wafer to create sources and drains;
forming a Co layer over said semiconductor wafer;
performing a first anneal to create a salicide;
removing an un-reacted portion of said Co layer; and
performing a second anneal.

31. The method of claim 30 wherein said step of performing a furnace thermal oxidation process is a substitute for a source/drain extension anneal of said semiconductor wafer.
